(19) United States
(12) Patent Application Publication
(10) Pub. No.: US 2010/0255427 A1
(43) Pub. Date: Oct. 7, 2010

(54) CONFORMAL PHOTO-SENSITIVE LAYER AND PROCESS

(75) Inventors: Chien-Wei WANG, Wufong Township (TW); Victor HUANG, Hsinchu (TW); Ching-Yu CHANG, Yuansun Village (TW)

Correspondence Address: Lowe Hauptman Ham & Berner, LLP (TSMC), 1700 Diagonal Road, Suite 300, Alexandria, VA, 22314, US

(73) Assignee: TAIWAN SEMICONDUCTOR MANUFACTURING COMPANY, LTD., Hsinchu (TW)

(21) Appl. No.: 12/751,250

(22) Filed: Mar. 31, 2010

Related U.S. Application Data
(60) Provisional application No. 61/166,235, filed on Apr. 2, 2009.

(51) Int. Cl. G03F 7/20

(52) U.S. Cl. 430/323

(57) ABSTRACT

The present disclosure provides a method for etching a substrate. The method includes forming a patterned photo-sensitive layer on the substrate; applying an etching chemical fluid to the substrate, wherein the patterned photo-sensitive layer includes an adhesion promoter and/or hydrophobic additive; removing the etching chemical fluid; and removing the resist pattern.

### CROSS-REFERENCE TO RELATED APPLICATIONS

The present application claims priority of U.S. Provisional Patent Application Ser. No. 61/166,235, filed on Apr. 2, 2009, which is incorporated herein by reference in its entirety.

### BACKGROUND

The semiconductor integrated circuit (IC) industry has experienced rapid growth. To make an integrated circuit, various material layers are patterned using a photolithography process. The photolithography process includes photoresist (resist) coating, exposing and developing. Currently, when forming a resist pattern on a wafer substrate having a material layer, such as a metal or dielectric film, the material layer can be etched by wet or dry etching. An additional rinse may be applied thereafter.

However, the isotropic nature of many etching processes, particularly wet etching processes, can cause issues with the transfer of a pattern from the resist pattern to the material layer. This is particularly a concern where the material layer is very thin. Undercutting (e.g., removal of the material layer beneath the resist pattern) may be caused by a lateral component of an isotropic etch. The undercutting may provide defects in patterning of the material layer such as imprecise dimension control. The undercutting can also reduce the surface area of adhesion between the resist pattern and the substrate, which may lead to defects such as peeling of the resist pattern during subsequent processes.

Though a dry etch process may lessen the isotropic nature of the etch, it may introduce further problems such as damage to the resist pattern, material layer, and/or underlying layers. These issues may be especially critical in fabricating a semiconductor device including a high-k gate dielectric/metal gate structure. The gate structure may include thin layers for which dimensions must be tightly controlled during patterning.

Accordingly, what is needed is a method for forming a resist pattern on a material layer being etched by wet chemical processes without undercut.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a cross-sectional view illustrating an embodiment of a conventional semiconductor device including undercutting.

FIGS. 2a through 2d are cross-sectional views of one embodiment of a semiconductor structure at various fabrication stages.

FIGS. 3a through 3d are cross-sectional views of another embodiment of a semiconductor structure at various fabrication stages.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

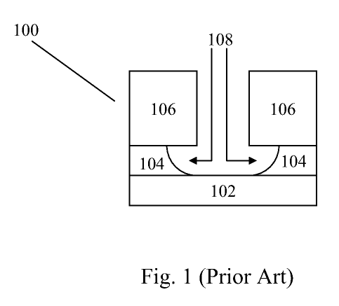

Referring now to FIG. 1, illustrated is a cross-sectional view of a conventional semiconductor device 100. The device includes a substrate 102, a material layer 104 (e.g., a layer to be patterned), and a patterned layer 106. The patterned layer 106 protects (masks) a portion of the material layer 104 leaving portions open (e.g., exposed). The patterned layer 106 typically includes a photo-sensitive material. However, other materials may be possible including metals, dielectrics, hard masks, and/or other suitable masking materials. An etching process has been performed which removed the open portion of the material layer 104 (e.g., not underlying the patterned layer 106). However, the semiconductor device 100 illustrates a disadvantage of conventional processes. The material layer 104 includes undercutting as illustrated by recesses 108. The recesses 108 underlie the patterned layer 106. This region of the material layer 104, though it may not be intended to be removed, is etched away by the isotropic-nature of a wet etching process.

The recesses 108 make it difficult to control the dimensions of a pattern formed on the material layer 104. Furthermore, the patterned layer 106 may cause defects. For example, as the surface area of adhesion between the patterned layer 106 and the material layer 104 is decreased, the patterned layer 106 may more easily peel off of the material layer 104.

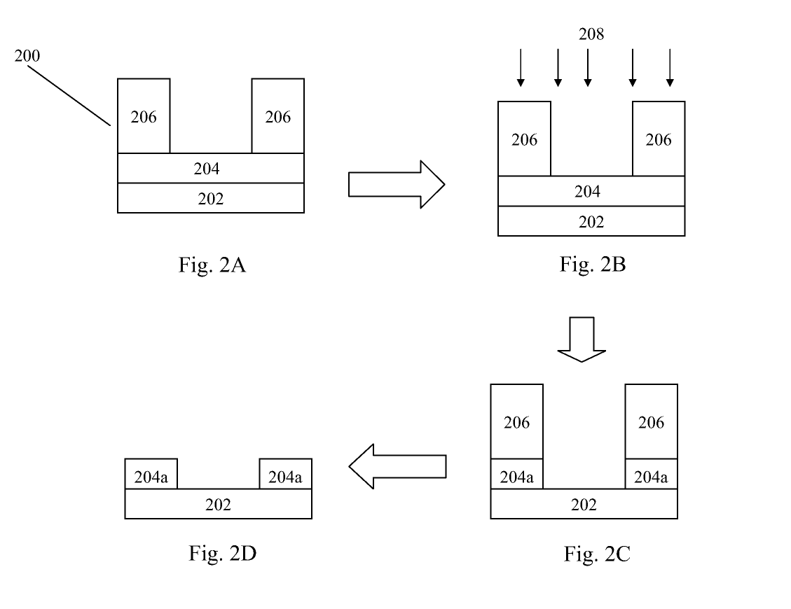

FIGS. 2a through 2d are sectional views of one embodiment of a semiconductor structure 200 at various fabrication stages. It is understood that FIGS. 2a to 2d have been simplified to better understand the inventive concepts of the present disclosure.

Referring now to FIG. 2a, the semiconductor structure 200 includes a semiconductor substrate 202. In an embodiment, the substrate 202 includes a silicon substrate (e.g., wafer) in crystalline structure. Other examples of the substrate 202 may include other elementary semiconductors such as germanium and diamond. Alternatively, the substrate 202 may include a compound semiconductor, such as silicon carbide, gallium arsenide, indium arsenide, or indium phosphide. The substrate 202 may include various doping configurations depending on design requirements (e.g., p-type substrate or n-type substrate). Further, the substrate 202 may include an epitaxial layer (epi layer), may be strained for performance enhancement, and/or may include a silicon-on-insulator (SOI) structure. The substrate may include isolation regions, active regions, doped regions, dielectric layers, conductive layers, and/or other suitable features.

The semiconductor structure 200 further includes a material layer 204 disposed on the substrate 202. The material layer 204 may include, for example, a conductive film or dielectric film. The material layer 204 may be between approximately 10 and 100 Angstroms in thickness, by way of example. If material layer 204 is a conductive film, the conductive film may have a resistivity of less than about 1×10⁻³ ohm-m. The conductive film preferably comprises a conductive material or metal alloy such as copper, aluminum, silver, tungsten, or combinations thereof. Alternatively, the conductive film may comprise other conductive materials. For example, the conductive film may be formed from any of a variety of suitable conducting materials, including: metal nitride, metal sulfide, metal selenide, metal silicide, and combinations thereof. If the metal film comprises MX_{y}, preferably y is between approximately 0.4 and 2.5, such as TiN, TaN or WN₂. The conductive film may be formed by various deposition techniques such as chemical vapor deposition (CVD), physical vapor deposition (PVD or sputtering), atomic layer deposition (ALD), plating, or other suitable technique. In alternate embodiments, the material layer 204 is a dielectric film comprising a high-k (high dielectric constant relative to a conventional silicon oxide) material. In an embodiment, the high-k dielectric material includes hafnium oxide (HfO₂). Other examples of high-k dielectrics include hafnium silicon oxide (HfSiO), hafnium silicon oxynitride (HfSiON), hafnium tantalum oxide (HfTaO), hafnium titanium oxide (HfTiO), hafnium zirconium oxide (HfZrO), combinations thereof, and/or other suitable materials. The high-k gate dielectric layer may be formed using ALD, PVD, CVD, and/or other suitable processes.

Referring also to FIG. 2a, a patterned photo-sensitive layer 206 is formed on the material layer 204. The patterned photo-sensitive layer 206 may be formed by photolithography, immersion lithography, or other suitable process. For example, the patterned photo-sensitive layer 206 may be formed using processes such as spin-coating, photolithography processes including exposure, bake, and development processes, etching (including ashing or stripping processes), and/or other processes. The photolithography exposing process may also be implemented or replaced by other proper methods such as maskless photolithography, electron-beam writing, ion-beam writing, and molecular imprint. The patterned photo-sensitive layer 206 is sensitive to particular exposure beam such KrF, ArF, EUV or e-beam light. In on example, the patterned photo-sensitive layer includes polymers, quencher, chromophore, solvent and chemical amplifier (CA) for 0.25 micron or advanced technology nodes. The CA includes photoacid generator (PAG). Though illustrated herein as a positive tone resist, use of a negative resist is also possible. The patterned photosensitive layer 206 may include a single layer or a multiple layer structure. To reduce the penetration and the lateral etch rate, the patterned photosensitive layer 206 further includes an adhesion promoter and/or hydrophobic additive incorporated into the patterned photosensitive layer 206. The adhesion promoter and/or hydrophobic additive are physically distributed in the patterned photosensitive layer 206 or chemically change the patterned photosensitive layer 206 to reduce the penetration and the lateral etch rate. The adhesion promoter may increase the adhesion between the material layer 204 and the patterned photo-sensitive layer 206 and may reduce the penetration. The hydrophobic additive may reduce the lateral etch rate by wet chemical. The patterned photo-sensitive layer 206 may provide a pattern including protecting (e.g., covering) a portion of the material layer and exposing (e.g., leaving open) a portion of the material layer 204. In an embodiment, the patterned photo-sensitive layer 206 provides a pattern associated with forming a gate structure.

Referring also to FIG. 2b, a wet etching process 208 is applied to the material layer 204 to remove the material layer 204 through the openings defined by the patterned photosensitive layer 206. The wet etch material may include solvent or chemical. In one embodiment, the solvent includes NMP, PGME, PGMEA, water, or DMSO, in various applications. In one embodiment, the chemical includes acid, base, oxidant, reductant, and surfactant. For example, the acid includes HCl, H₂SO₄, HNO₃, HF, or phosphoric acid. The base includes ammonia or TMAH. The oxidant includes

H₂O₂, HNO₃, or O₃. The surfactant includes polyethene oxide, polypropylene oxide, polybutylenes oxide, or polypentylene oxide, and fluoroalkylsulfonate such as PFOS.

Referring also to FIG. 2c, a patterned material layer 204a is formed after removing the material layer 204 through the openings defined by the patterned photo-sensitive layer 206. A rinse step may be implemented to remove the etch solution after the completion of the wet etch. Referring also to FIG. 2d, the patterned photo-sensitive layer 206 is stripped after the wet etching process 208. In this case, the surface of the patterned material layer 204a underlying the patterned photo-sensitive layer 206 at the opening edge is not damaged. The patterned photosensitive layer 206 can be properly transferred to the substrate.

In various embodiments, the patterned photo-sensitive layer 206 includes an adhesion promoter. In one example, the adhesion promoter having polymer structure is a compound of formula (1);

R₁—X

wherein R₁ is hydrophobic straight/branched/cyclic alkyl or alkoxyl chains having carbon numbers between 1 and 18; and X is the ligand. The ligand could be single dendate or multidendate and comprise at least one of the functional groups:
SH; S; S—CN; O—NO₂; N—N₂; OH; [O—C(═O)—C(═O)—O]; N═C═S; CH₃CN; C₅H₅N; NH₃; NO²⁻; O—N—O⁻; CN⁻; CO; COO—; COOH; amine; amide; halide, phosphine; pyridine; alkene; alkyne, and an aromatic carbon ring.
The alkyl ligand may adhere to the material layer 204 to increase the adhesion between the material layer 204 and the patterned photo-sensitive layer 206. The polymer structure includes an alkyl chain. The M. W. of alkyl ligand amount is less than 90% M. W. of the alkyl chain.

In various embodiments, the patterned photo-sensitive layer 206 includes an adhesion promoter. In one example, the adhesion promoter having polysiloxane structure is a compound of formula (2);

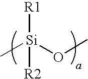

wherein a is mer unit number between 1 and 10; R₁ and R₂ are functional groups comprising a material selected from the group consisting of H, OH, halide, straight/cyclic/branched alkyl/alkoxyl/fluoroalkyl/fluoroalkoxyl chain having carbon number between 1 and 15; The alkyl, alkoxyl, fluoroalkyl, and fluoroalkoxyl chain may further comprise a pendant group selected from H, halide, alkoxyl, ester, —CN, —NCO, —OCN, COOH, OH, amide, amine, lactone, lactam, thio, and sulfonyl groups with the M. W. of the pendant group is less than 90% M. W. of the alkyl, alkoxyl, fluoroalkyl, and fluoroalkoxyl chain. M. W. of the siloxane is about between 100 and 2000.

In various embodiments, the patterned photo-sensitive layer 206 includes a hydrophobic additive. In one example, the hydrophobic additive including fluoroalkane is a compound of formula (3);

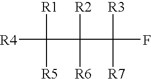

wherein R₁, R₂, R₃, R₄, R₅, R₆ and R₇ are functional groups comprising a material selected from the group consisting of H, OH, halide, straight/cyclic/branched alkyl/alkoxyl/fluoroalkyl/fluoroalkoxyl chain having carbon number between 1 and 15; The alkyl, alkoxyl, fluoroalkyl, fluoroalkoxyl chain may further comprises a pendant group selected from H, halide, alkoxyl, ester, —CN, —NCO, —OCN, COOH, OH, amide, amine, lactone, lactam, thio, and sulfonyl groups with the M. W. of the pendant group is less than 90% M. W. The M. W. of fluoroalkane is about between 100 and 20000.

In various embodiments, the patterned photo-sensitive layer 206 includes a hydrophobic additive. In one example, the hydrophobic additive including fluorosurfactant is a compound of formula (4);

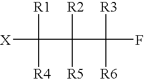

wherein X comprises a material selected from the group consisting of sulfate, sulfite, phosphate, nitrate, nitrite, and carboxylic acid group; R₁, R₂, R₃, R₄, R₅, and R₆ are functional groups comprising a material selected from the group consisting of H, OH, halide, straight/cyclic/branched alkyl/alkoxyl/fluoroalkyl/fluoroalkoxyl chain having carbon number between 1 and 15; The straight/cyclic/branched alkyl/alkoxyl/fluoroalkyl/fluoroalkoxyl chain may further comprise a pendant group selected from H, halide, alkoxyl, ester, —CN, —NCO, —OCN, COOH, OH, amide, amine, lactone, lactam, thio, and sulfonyl groups with the M. W. of the pendant group is less than 90% M. W.

In various embodiments, the patterned photo-sensitive layer 206 includes a hydrophobic additive. In one example, the hydrophobic additive including fluorosiloxane is a compound of formula (5)

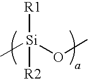

wherein a is mer unit number between 1 and 15; R₁ and R₂ are functional groups comprising a material selected from the group consisting of H, OH, halide straight/cyclic/branched alkyl/alkoxyl/fluoroalkyl/fluoroalkoxyl chain having carbon number between 1 and 15. At least one of the R₁ or R₂ is fluoroalkyl/fluoroalkoxyl chain. The straight/cyclic/branched alkyl/alkoxyl/fluoroalkyl/fluoroalkoxyl chain may further comprises a pendant groups selected from H, halide, alkoxyl, ester, —CN, —NCO, —OCN, COOH, OH, amide, amine, lactone, lactam, thio, and sulfonyl groups with the M. W. of the pendant group is less than 90% M. W. MW. of fluorosiloxane is about between 100 and 20000.

In various embodiments, the patterned photo-sensitive layer 206 includes a hydrophobic additive. In one example, the hydrophobic additive including a fluorinated polymer having fluorine content about between 0.1% and 40% M. W. of the fluorinated polymer. In one example, the fluorinated polymer may be fluorinated acrylate or fluorinated methacrylate moiety. The fluorinated polymer is a compound of formula (6);

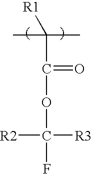

wherein R₁ is H or methyl group; R₂ and R₃ are functional groups comprising a material selected from the group consisting of H, OH, halide, straight/cyclic/branched alkyl/alkoxyl/fluoroalkyl/fluoroalkoxyl chain having carbon number between 1 and 6 The straight/cyclic/branched alkyl/alkoxyl/fluoroalkyl/fluoroalkoxyl chain may further comprise a pendant group selected from H, halide, alkoxyl, ester, —CN, —NCO, —OCN, COOH, OH, amide, amine, lactone, lactam, thio, and sulfonyl groups with the M. W. of the pendant group is less than 90% M. W. In another example, the fluorinated polymer may include fluorinated polymer backbone having a compound of formula (7);

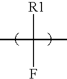

wherein R₁ is H, halide or alkyl group. In another example, the fluorinated polymer may be fluoroalkyl, fluoroalkoxyl or fluoroalcohol. The fluorinated polymer is a compound of formula (8);

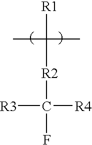

wherein R₁ is H or methyl group; R₂ comprises a material selected from the group consisting of H, OH, halide, straight/cyclic/branched alkyl/alkoxyl/fluoroalkyl/fluoroalkoxyl chain having carbon number between 1 and 6. The straight/cyclic/branched alkyl/alkoxyl/fluoroalkyl/fluoroalkoxyl chain may further comprise a pendant group selected from H, halide, alkoxyl, ester, —CN, —NCO, —OCN, COOH, OH, amide, amine, lactone, lactam, thio, and sulfonyl groups with the M. W. of the pendant group is less than 90% M. W. In another example, the fluorinated polymer may be 2-fluoroisopropylstyrene, fluoroisopropanolstyrene, 3-fluoroisopropylstyrene, fluoroisopropanolstyrene, 4fluoroisopropylstyrene, or fluoroisopropanolstyrene. The fluorinated polymer is a compound of formula (9);

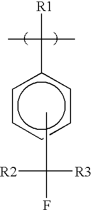

wherein R₁ is H or methyl group; R₂ and R₃ are functional groups comprising a material selected from the group consisting of H, OH, straight/cyclic/branched alkyl/alkoxyl/fluoroalkyl/fluoroalkoxyl chain having carbon number between 1 and 6. The straight/cyclic/branched alkyl/alkoxyl/fluoroalkyl/fluoroalkoxyl chain may further comprise a pendant group selected from H, halide, alkoxyl, ester, —CN, —NCO, —OCN, COOH, OH, amide, amine, lactone, lactam, thio, and sulfonyl groups with the M. W. of the pendant group is less than 90% M. W.

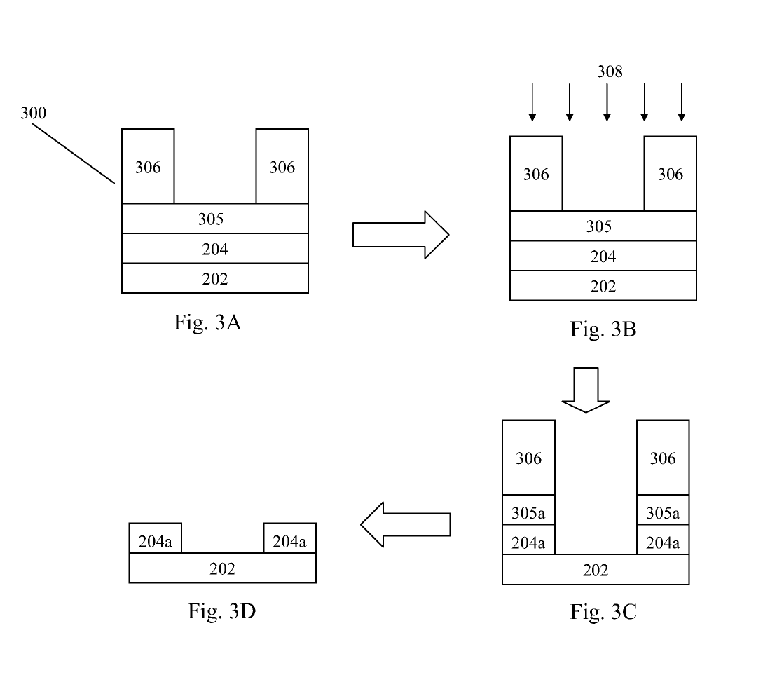

FIGS. 3a through 3d are sectional views of one embodiment of a semiconductor structure 300 at various fabrication stages. It is understood that FIGS. 3a to 3d have been simplified to better understand the inventive concepts of the present disclosure. The semiconductor structure 300 is similar to the semiconductor device 200 of FIG. 2. Accordingly, similar features 202, 204, and 204a in FIGS. 2 and 3 are numbered the same for the sake of simplicity and clarity.

Referring now to FIG. 3a, the semiconductor structure 300 includes a semiconductor substrate 202. The semiconductor structure 300 further includes a material layer 204 disposed on the semiconductor substrate 202. Additionally, a soluble adhesion promoter layer 305 is formed on the substrate, overlying the material layer 204. The soluble adhesion promoter layer 305 includes a composition such that it is soluble in water and thus, removable from the substrate. The soluble adhesion promoter layer 305 may include a single layer or a multiple layer structure. The soluble adhesion promoter layer 305 includes an adhesion promoter incorporated into the soluble adhesion promoter layer 305. The adhesion promoter may increase the adhesion between the material layer 204 and the soluble adhesion promoter layer 305 and may reduce the penetration. The adhesion promoter is physically distributed in the soluble adhesion promoter layer 305 or chemically change the soluble adhesion promoter layer 305 to reduce the penetration and the lateral etch rate. A patterned photo-sensitive layer 306 may be formed by photolithography, immersion lithography, or other suitable process as was discussed above. The patterned photo-sensitive layer 306 may has an adhesion promoter and/or hydrophobic additive incorporated into the patterned photo-sensitive layer 306. The adhesion promoter and/or hydrophobic additive are physically distributed in the patterned photo-sensitive layer 306 or chemically change the patterned photo-sensitive layer 306 to reduce the penetration and the lateral etch rate.

In one embodiment, the soluble adhesion promoter layer 305 includes an adhesion promoter. In one example, the adhesion promoter having a polymer structure is a compound of formula (10);

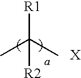

wherein a is mer unit numbered between 5 and 100; R₁ and R₂ are functional groups comprising hydrophobic alkyl chain having carbon number between 1 and 15; X is an alkyl ligand with M. W. about between 100 and 2000; The alkyl ligand comprises a material selected from the group consisting of SH, PH₃, halide, hydroxyl, epoxyl, cyano, amine, amide, and unsaturated car group (alkene, alkyne, aromatic). The alkyl ligand may adhere to the material layer 204 to increase the adhesion between the material layer 204 and the patterned photo-sensitive layer 306. The polymer structure includes an alkyl chain. M. W. of the alkyl ligand is less than 90% M. W. of the alkyl chain.

In various embodiments, the soluble adhesion promoter layer 305 includes an adhesion promoter. In one example, the adhesion promoter having a polysiloxane structure is a compound of formula (11);

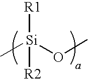

wherein a is mer unit numbered between 1 and 10; R₁ and R₂ are functional groups comprising a material selected from the group consisting of H, OH, halide, alkyl, alkoxyl, fluoroalkyl, and fluoroalkoxyl chain having carbon number between 1 and 15; The alkyl, alkoxyl, fluoroalkyl, and fluoroalkoxyl chain comprises a material selected from the group consisting of OH, amine, SH, loctone, amide, carbonxylic acid, and ester functional groups. M. W. of the function group is less than 90% M. W. of the alkyl, alkoxyl, fluoroalkyl, and fluoroalkoxyl chain. M. W. of siloxane is about between 100 and 2000.

Referring also to FIG. 3b, a wet etching process 308 is applied to the soluble adhesion promoter layer 305 being removable (e.g., soluble) in water to remove the soluble adhesion promoter layer 305 in the portions not protected by the remaining patterned photo-sensitive layer 306. Then the wet etching process 308 proceeds to the material layer 204 to remove the material layer 204 through the openings defined by the patterned photo-sensitive layer 306 and the patterned soluble adhesion promoter layer 305a. The wet etch material may include solvent or chemical. In one embodiment, the solvent includes NMP, PGME, PGMEA, water, or DMSO, in various applications. In one embodiment, the chemical includes acid, base, oxidant, reductant, and surfactant. The acid includes HCl, H₂SO₄, HNO₃, HF, or phosphoric acid. The base includes ammonia or TMAH. The oxidant includes H₂O₂, HNO₃, or O₃. The surfactant includes polyethene oxide, poly propylene oxide, poly butylenes oxide, or polypentylene oxide. The wet-etch materials to remove the soluble adhesion promoter layer 305 and the material layer 204 may be same or different.

Referring also to FIG. 3c, a patterned soluble adhesion promoter layer 305a and a patterned material layer 204a are formed after removing the soluble adhesion promoter layer 305 and the material layer 204 through the openings defined by the patterned photo-sensitive layer 306. A rinse step may be implemented to remove the etch solution after the completion of the wet etch. Referring also to FIG. 3d, the patterned photo-sensitive layer 306 and the soluble adhesion promoter layer 305a are stripped after the wet etching process 308. In this case, the surface of the patterned material layer 204a underlying the patterned photo-sensitive layer 306 at the opening edge is not damaged. The patterned photo-sensitive layer 306 can be properly transferred to the substrate.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. An etching method comprising:
forming a material layer on a substrate;
forming a photo-sensitive layer over the material layer, wherein the photo-sensitive layer comprises an adhesion promoter, wherein the adhesion promoter with Molecular Weight (M. W.) about between 100 and 2000 comprises at least one of a polymer with an alkyl ligand or a siloxane;
patterning the photo-sensitive layer to form a patterned photo-sensitive layer; and
etching the material layer through the patterned photo-sensitive layer.

2. The method of claim 1, wherein the alkyl ligand comprises a functional group selected from the group consisting of SH, PH₃, halide, hydroxyl, epoxyl, cyano, amine, amide, and unsaturated carbon group (alkene, alkyne, aromatic).

3. The method of claim 1, wherein the adhesion promoter is an alkyl ligand

4. The method of claim 3, wherein M. W. of the ligand is less than 90% M. W. of the alkyl chain.

5. The method of claim 1, wherein the siloxane comprises polysiloxane, wherein polysiloxane comprises between 1 and 10 mer units.

6. The method of claim 5, wherein the polysiloxane comprises functional groups, wherein the functional groups comprise a material selected from the group consisting of H, OH, straight/cyclic/branched alkyl/alkoxyl/fluoroalkyl/fluoroalkoxyl chain having carbon number between 1 and 15.

7. The method of claim 6, wherein the straight/cyclic/branched alkyl/alkoxyl/fluoroalkyl/fluoroalkoxyl chain may further comprise a pendant group selected from H, halide, alkoxyl, ester, —CN, —NCO, —OCN, COOH, OH, amide, amine, lactone, lactam, thio, and sulfonyl groups with the M. W. of the pendant group is less than 90% M. W.

8. An etching method comprising:
forming a material layer on a substrate;
forming a photo-sensitive layer over the material layer, wherein the photo-sensitive layer comprises an hydrophobic additive, wherein the hydrophobic additive includes a material selected from the group consisting of fluorinated polymer, fluoroalkane, fluorosiloxane, and fluorosurfactant;
patterning the photo-sensitive layer to form a patterned photo-sensitive layer; and etching the material layer through the patterned photo-sensitive layer.

9. The method of claim 8, wherein the fluorinated polymer includes fluorine content about between 0.1% and 40% M. W. of the fluorinated polymer.

10. The method of claim 8, wherein the fluorinated polymer includes fluorinated acrylate or fluorinated methacrylate moiety.

11. The method of claim 8, wherein the fluorinated polymer includes fluorinated backbone.

12. The method of claim 8, wherein the fluorinated polymer includes fluoroalkyl, fluoroalkoxyl or fluoroalcohol.

13. The method of claim 8, wherein the fluorinated polymer includes 2fluoroisopropylstyrene, fluoroisopropanolstyrene, 3-fluoroisopropylstyrene, fluoroisopropanolstyrene, 4-fluoroisopropylstyrene, or fluoroisopropanolstyrene.

14. The method of claim 8, wherein M. W. of fluoroalkane or fluorosiloxane is about between 100 and 20000.

15. The method of claim 8, wherein M. W. of fluorosurfactant is about between 100 and 1000.

16. An etching method comprising:
forming a material layer on a substrate;
forming a soluble adhesion promoter layer over the material layer, wherein the soluble adhesion promoter with M. W. about between 100 and 2000 includes at least one of a polymer with an alkyl ligand or a siloxane;
forming a photo-sensitive layer over the soluble adhesion promoter layer;
patterning the photo-sensitive layer to form a patterned photo-sensitive layer;
etching the soluble adhesion promoter layer through the patterned photo-sensitive layer to form a patterned soluble adhesion promoter layer; and etching the material layer through the patterned photo-sensitive layer and the patterned soluble adhesion promoter layer.

17. The method of claim 16, wherein the alkyl ligand includes is a material selected from the group consisting of SH; S; S—CN; O—NO₂; N—N₂; OH; [O—C(═O)—C(═O) O]; N═C═S; CH₃CN; C₅H₅N; NH₃; N—O₂; O—N—O; CN; CO; COO—; COOH; amine; amide; halide, phosphine; pyridine; alkene; alkyne, and an aromatic carbon ring.

18. The method of claim 16, wherein M. W. of the ligand amount is less than 90% M. W. of the alkyl chain.

19. The method of claim 16, wherein the siloxane comprises polysiloxane, wherein polysiloxane has a mer unit number between 1 and 10.

20. The method of claim 19, wherein the polysiloxane includes a functional group, wherein the functional group includes a material selected from the group consisting of H, OH, halide, alkyl, alkoxyl, fluoroalkyl, and fluoroalkoxyl chain having carbon number between 1 and 15.
